(19) United States
(12) Patent Application Publication
(10) Pub. No.: US 2026/0324157 A1
(43) Pub. Date: Oct. 15, 2026

(54) DISPLAY APPARATUS

(71) Applicant: LG Display Co., Ltd., Seoul (KR)

(72) Inventors: Jinhwa SHIN, Paju-si (KR); Hansaem KANG, Paju-si (KR); Bongseok CHOI, Paju-si (KR); Doyoung KWAK, Paju-si (KR); Jongmin JANG, Paju-si (KR); Youngsuk HWANG, Paju-si (KR)

(21) Appl. No.: 19/571,422

(22) Filed: Mar. 18, 2026

(30) Foreign Application Priority Data
Apr. 14, 2025 (KR) 10-2025-0048135

(51) Int. Cl. H10H 29/39; H10H 29/80

(52) U.S. Cl. CPC H10H 29/39; H10H 29/842

(57) ABSTRACT

A display apparatus includes: a substrate; a light-emitting element disposed on the substrate; and a common connection electrode associated with the substrate and configured to electrically couple to the light-emitting element, in which the light-emitting element includes: a first electrode disposed on the substrate; a light-emitting layer disposed on the first electrode; a second electrode disposed on the light-emitting layer; and a passivation film covering at least side surfaces of the light-emitting layer, and the first electrode extends beyond the passivation film such that a portion of the first electrode is located outward of the passivation film.

### CROSS REFERENCE TO RELATED APPLICATION

This application claims priority from and the benefit of Korean Patent Application No. 10-2025-0048135, filed on Apr. 14, 2025, which is hereby incorporated by reference for all purposes as if fully set forth herein.

### BACKGROUND

### Field

Embodiments of the invention relate generally to a display apparatus, and more particularly, to a display apparatus capable of providing a smooth electrical connection to a light-emitting diode (LED) element.

### Discussion of the Background

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, the OLED display apparatus is a self-luminous type, which provides a wider viewing angle and a higher contrast ratio. In addition, because a separate backlight is not required, the OLED display apparatus can be made lighter and thinner and can consume less power consumption than the LCD apparatus. Furthermore, the OLED display apparatus also operate at relatively low voltage, provide a fast response time, and can be manufacture at relatively low cost.

However, the OLED display apparatus using organic materials is prone to defective pixels, such as oxidation between an organic light-emitting layer and electrodes due to moisture and oxygen penetration. Accordingly, various technical configurations are required to minimize or at least reduce such penetration.

To address the above problems, research and development has recently been directed to display apparatuses that use light-emitting diodes (LEDs) using inorganic materials as light-emitting elements. Such light-emitting display apparatuses are attracting attention as next-generation display apparatuses because they have high image quality and high reliability.

The above information disclosed in this Background section is only for understanding of the background of the inventive concepts, and, therefore, it may contain information that does not constitute prior art.

### SUMMARY

Embodiments of the present disclosure provide a display apparatus and a method of manufacturing the same, capable of providing a smooth electrical connection to a light-emitting diode (LED) element.

Embodiments of the present disclosure also provide a display device and a method of manufacturing the same, capable of facilitating stable contact with the LED element.

Embodiments of the present disclosure still provide a display device and a method of manufacturing the same, capable of improving light extraction efficiency.

Embodiments of the present disclosure also provide a display device and a method of manufacturing the same, capable of preventing or at least reducing a short circuit between a connection electrode and an active layer.

Embodiments of the present disclosure still provide a display device and a method of manufacturing the same, capable of improving process efficiency and reducing process costs by separating a transfer process from an electrode connection process.

Additional features of the inventive concepts will be set forth in the description which follows, and in part will be apparent from the description, or may be learned by practice of the inventive concepts.

According to an embodiment of the present disclosure, a display apparatus includes a substrate, a light-emitting element disposed on the substrate, and a common connection electrode associated with the substrate and configured to electrically couple to the light-emitting element, in which the light-emitting element includes a first electrode over the substrate, a light-emitting layer over the first electrode, a second electrode over the light-emitting layer, and a passivation film covering at least side portions of the light-emitting layer, and the first electrode extends beyond the passivation film such that a portion of the first electrode is located outward of the passivation film.

The common connection electrode may contact side surfaces of the first electrode.

The common connection electrode may be configured to be applied with a high-potential voltage high-potential voltage.

A planar size of the first electrode may be greater than a planar size of the light-emitting layer.

An entire area of the light-emitting layer may overlap the first electrode in a thickness direction.

Side surfaces of the first electrode may protrude further outward than an outer surface of the passivation film.

The first electrode may extend along the outer surface of the passivation film near edges of the passivation film.

A portion of the passivation film may be disposed between the light-emitting layer and the first electrode.

The passivation film may surround the light-emitting layer along edges of the light-emitting layer.

The first electrode may contact an outer surface of the passivation film.

The display apparatus may further include an adhesive layer disposed on the substrate, a first insulating layer disposed on the adhesive layer, and a second insulating layer disposed on the first insulating layer. The first insulating layer and the second insulating layer may cover at least a portion of the light-emitting element, and the second insulating layer may define an opening exposing side surfaces and an upper surface of the second electrode.

The display apparatus may further include a pixel connection electrode disposed on the second insulating layer. The pixel connection electrode may contact the upper surface and side surfaces of the second electrode exposed by the opening.

The display apparatus may further include a transistor disposed on the substrate. The pixel connection electrode may be electrically connected to the transistor.

The display apparatus may further include a first planarization layer disposed on the transistor; and a first connection electrode and a second connection electrode disposed on the first planarization layer. The first connection electrode may be electrically connected to the transistor.

The display apparatus may further include: a second planarization layer disposed on the first connection electrode and the second connection electrode; and a third connection electrode and a fourth connection electrode disposed on the second planarization layer. The third connection electrode may be electrically connected to the first connection electrode, and the fourth connection electrode may be electrically connected to the second connection electrode.

The adhesive layer, the first insulating layer and the second insulating layer may define a second through-hole exposing the third connection electrode, and the pixel connection electrode may be electrically connected to the third connection electrode exposed by the second through-hole.

The opening further may expose a portion of the passivation film.

The display apparatus may further include a pixel connection electrode disposed on the second insulating layer. The pixel connection electrode may contact the passivation film exposed by the opening.

The light-emitting layer may include: a first semiconductor layer disposed on the first electrode; an active layer disposed on the first semiconductor layer; and a second semiconductor layer disposed on the active layer. A width of the light-emitting layer may decrease from the first semiconductor layer toward the second semiconductor layer.

Side surfaces of the second electrode may be protrude further toward the light-emitting layer than other regions of the second electrode.

The second electrode may overlap the passivation film in a thickness direction.

According to another embodiment of the present disclosure, a display apparatus includes a substrate, an adhesive layer disposed on the substrate, a light-emitting element supported by the adhesive layer, wherein the light-emitting element includes a first electrode over the adhesive layer, a light-emitting layer over the first electrode, a second electrode over the light-emitting layer, and a passivation film covering at least side regions of the light-emitting layer, and an upper surface and side surfaces of the second electrode may be exposed.

The display apparatus may further include: a first insulating layer disposed on the adhesive layer and covering a portion of a lower portion of the light-emitting element; a second insulating layer disposed on the first insulating layer; and a common connection electrode disposed between the adhesive layer and the first insulating layer. The common connection electrode may contact side surfaces of the first electrode.

Side surfaces of the first electrode may protrude further outward than an outer surface of the passivation film.

The display apparatus may further include a pixel connection electrode disposed on the second insulating layer. The second insulating layer may define an opening exposing an upper surface and side surfaces of the second electrode, and the pixel connection electrode may contact the upper surface and side surfaces of the second electrode exposed by the opening.

The first electrode may extend beyond the passivation film such that a portion of the first electrode is located outward of the passivation film.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view of a display apparatus according to an embodiment.

FIG. 2 is a schematic view illustrating a cross-sectional structure of a sub-pixel according to an embodiment.

FIG. 3 is an enlarged schematic view of area Q1 in FIG. 2.

FIGS. 4, 5, 6, 7, 8, 9, 10, 11, and 12 are schematic views illustrating each operation of a process of manufacturing the display apparatus according to an embodiment.

FIG. 13 is a schematic cross-sectional view of a display apparatus according to another embodiment.

FIG. 14 is a schematic cross-sectional view of a display apparatus according to still another embodiment.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

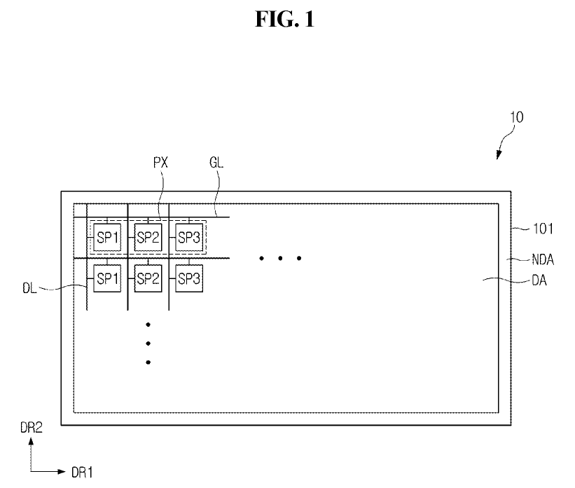

FIG. 1 is a schematic plan view of a display apparatus according to an embodiment.

Referring to FIG. 1, a display apparatus 10 according to an embodiment of the present disclosure may be applied to a TV, a signage, a mobile terminal such as a cell phone or smart phone, a computer display such as a laptop or desktop, a head-up display (HUD) for a vehicle, a display backlight unit, a virtual reality (VR), augmented reality (AR), or mixed reality (MR) display, etc. However, the configuration according to the embodiments described herein may be applied to any display-capable apparatus in the same manner even when a new product type is developed in the future.

The display apparatus 10 may use a micro light-emitting diode (LED) as a display element, but is not limited thereto.

The display apparatus 10 may include a flexible display manufactured on a thin, flexible substrate. A flexible display may maintain the characteristics of a conventional flat panel display and may be bent or rolled like paper.

The display apparatus 10 may include a display area DA in which a plurality of pixels PX are disposed, and a non-display area NDA in which an image is not displayed. The display apparatus 10 may include the substrate 110 that provides a space in which the plurality of pixels PX may be disposed.

The display area DA may display images, videos, pictures, etc., and include a plurality of pixels PX. The non-display area NDA does not display a screen and may also be referred to as an edge area or a bezel area. The non-display area NDA may be disposed outside the display area DA, but is not limited thereto. The non-display area NDA may be disposed around the display area DA, but is not limited thereto. The non-display area NDA may be disposed to surround the display area DA, but is not limited thereto.

The non-display area NDA may be defined as an area on the substrate 110 excluding the display area DA and may have a relatively narrow width (or size) compared to the display area DA but is not limited thereto.

The pixel PX may include a plurality of sub-pixels. For example, the pixel PX may include a plurality of sub-pixels SP1, SP2, and SP3, and the sub-pixels SP1, SP2, and SP3 may emit red, blue, and green light, respectively. However, various embodiments of the present disclosure are not limited thereto, and the pixel PX may also include sub-pixels that emit light of white, etc. In another embodiment, the sub-pixels SP1, SP2, and SP3 may emit cyan, magenta and yellow light, respectively. The sub-pixels SP1, SP2, and SP3 may be sequentially disposed in a first direction DR1. However, various embodiments of the present disclosure are not limited thereto.

The pixel PX may be repeatedly disposed in the first direction DR1 and a second direction DR2. Specifically, each of the sub-pixels SP1, SP2, and SP3 may be alternately disposed in the first direction DR1. Each of the sub-pixels SP1, SP2, and SP3 may be repeatedly disposed in the second direction DR2.

The display apparatus 10 may further include a gate line GL and a data line DL that are electrically connected to the sub-pixels SP1, SP2, and SP3 of each pixel PX. The gate line GL and the data line DL may provide necessary signals to the sub-pixels SP1, SP2, and SP3 of each pixel PX. The display apparatus 10 may further include a gate line GL and a data line DL that are electrically connected to the sub-pixels SP1, SP2, and SP3 of each pixel PX. The gate line GL and the data line DL may provide necessary signals to the sub-pixels SP1, SP2, and SP3 of each pixel PX.

The gate line GL may extend in the first direction DR1 and may be repeatedly disposed in the second direction DR2. The data line DL may extend in the second direction DR2 different from the first direction DR1 and may be repeatedly disposed in the first direction DR1. The gate line GL and the data line DL may intersect each other. However, various embodiments of the present disclosure are not limited thereto.

The substrate 110 may be an array substrate on which transistors are formed and may be made of a plastic material or glass material, but is not limited thereto.

The substrate 110 may be made of the flexible polymer film. For example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

In one example, the substrate 110 may include an opaque or colored polyimide material. In this case, the display apparatus 10 may further include a back plate coupled to a rear surface of the substrate 110 to maintain the substrate 110 in a flat surface state.

In one example, the back plate may include a plastic material, for example, a polyethylene terephthalate material.

In one example, the substrate 110 may be a glass substrate. For example, the glass substrate 110 may be a thin glass substrate having a thickness of about 100μm or less and may have flexible properties.

In addition, the substrate 110 may be formed by bonding two or more substrates or being divided into two or more layers.

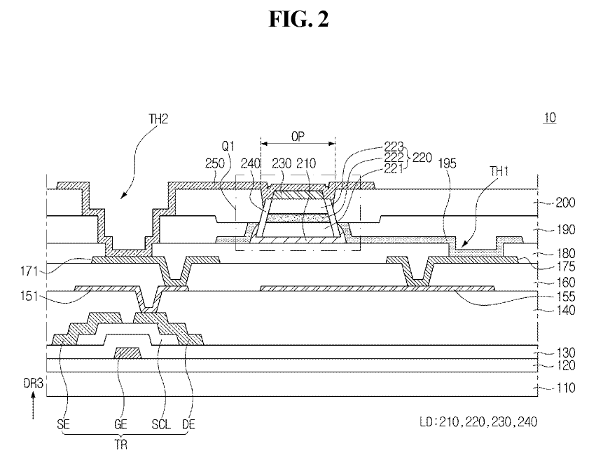

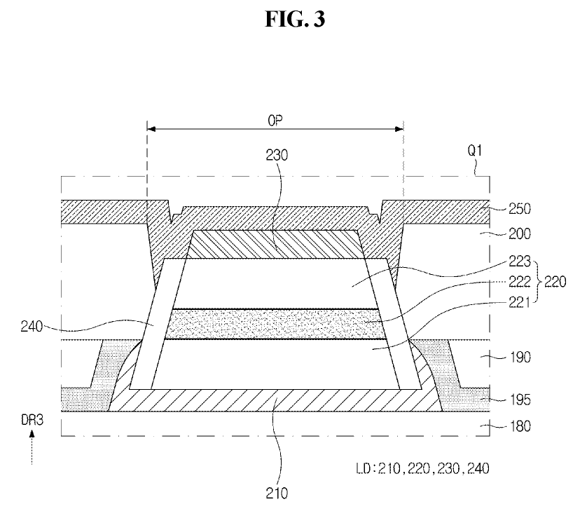

FIG. 2 is a schematic view illustrating a cross-sectional structure of a sub-pixel according to an embodiment. FIG. 3 is an enlarged schematic view of area Q1 in FIG. 2.

Referring to FIGS. 2 and 3, the display apparatus 10 may further include a transistor TR and a light-emitting element LD that are disposed on the substrate 110. In addition, the display apparatus 10 may further include lines electrically connecting the transistor TR to the light-emitting element LD, and at least one insulating layer disposed between the components. For example, at least one insulating layer may be disposed on or over the substrate 110.

A buffer layer 120 may be disposed on the substrate 110. The buffer layer 120 may minimize or at least reduce the diffusion of moisture or impurities from the substrate 110. The buffer layer 120 may be made of silicon oxide (SiOₓ), silicon nitride (SiNₓ), etc. The buffer layer 120 may be formed of a single layer or multiple layers made of silicon oxide (SiOₓ), silicon nitride (SiNₓ), etc., but is not limited thereto.

The transistor TR may be disposed on the buffer layer 120. The transistor TR may be used as a driving element of the light-emitting element LD. The transistor TR may be a driving transistor but is not limited thereto.

The transistor TR may be a thin-film transistor (TFT), an N-channel metal oxide semiconductor (NMOS), a P-channel metal oxide semiconductor (PMOS), a complementary metal oxide semiconductor (CMOS), a field effect transistor (FET), etc., but is not limited thereto.

The following description will be provided assuming that a plurality of transistors TR are thin-film transistors, but various embodiments of the present disclosure are not limited thereto.

Each of the plurality of transistors TR may include a gate electrode GE, an active layer SCL, a source electrode SE, and a drain electrode DE.

The gate electrode GE may be disposed on the buffer layer 120. For example, the gate electrode GE may be patterned and disposed on the buffer layer 120. The gate electrode GE may be made of a conductive material, such as copper (Cu), aluminum (Al), molybdenum (Mo), titanium (Ti), or an alloy thereof, but is not limited thereto.

The gate insulating layer 130 may be disposed on the gate electrode GE. The gate insulating layer 130 may be disposed between the gate electrode GE and the active layer SCL. The gate insulating layer 130 may insulate the gate electrode GE from the active layer SCL and may be made of an insulation material. For example, the gate insulating layer 130 may be formed of a single layer or multiple layers made of silicon oxide (SiOₓ), silicon nitride (SiNₓ), etc., but is not limited thereto.

The active layer SCL may be disposed on the gate insulating layer 130. For example, the active layer SCL may be made of an oxide semiconductor, amorphous silicon, polysilicon, etc., but is not limited thereto.

The source electrode SE and the drain electrode DE may be disposed to be spaced apart from each other on the active layer SCL. The source electrode SE and the drain electrode DE may be electrically connected to the active layer SCL. The source electrode SE and the drain electrode DE may be made of a conductive material, such as copper (Cu), aluminum (Al), molybdenum (Mo), titanium (Ti), or an alloy thereof, but are not limited thereto.

In the aspects of the present disclosure, a source electrode and a drain electrode may be distinguished from each other, for convenience of description. However, the source electrode and the drain electrode may be used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In FIG. 2, the gate electrode GE is illustrated as being disposed below the active layer SCL, but is not limited thereto. For example, in FIG. 2, the active layer SCL is illustrated as being disposed between the source electrode SE and the drain electrode DE, and the gate electrode GE, but is not limited thereto. For example, the active layer SCL and the gate insulating layer 130 may be illustrated as being disposed between the source electrode SE and the drain electrode DE, and the gate electrode GE, but is not limited thereto.

For example, the gate electrode GE may also be disposed above the active layer SCL. In this case, the gate electrode GE may be disposed between the source electrode SE and the drain electrode DE, and the active layer SCL.

A first planarization layer 140 may be disposed on the transistor TR. The first planarization layer 140 may planarize an upper portion of the substrate 110 including the plurality of transistors TR.

The first planarization layer 140 may be formed of a single layer or multiple layers and may be made of an organic material. For example, the first planarization layer 140 may be made of an acrylic-based organic material but is not limited thereto. The first planarization layer 140 includes a contact hole for electrically connecting the transistor TR to the first connection electrode 151.

The first planarization layer 140 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

Although not illustrated, a protective layer may be further disposed between the first planarization layer 140 and the transistor TR to protect underlying components.

A first connection electrode 151 and a second connection electrode 155 may be disposed on the first planarization layer 140.

The first connection electrode 151 and the second connection electrode 155 may be disposed on the same layer and made of the same material but is not limited thereto. For example, the first connection electrode 151 and the second connection electrode 155 may be made of different materials. The first connection electrode 151 and the second connection electrode 155 may be disposed on the first planarization layer 140 and made of a metallic material. For example, the first connection electrode 151 and the second connection electrode 155 may include a light-reflecting conductive material, and the light-reflecting conductive material may include at least one selected from aluminum (Al), silver (Ag), gold (Au), platinum (Pt), copper (Cu), etc.

The first connection electrode 151 may overlap the transistor TR in a third direction DR3 (or thickness direction). The first connection electrode 151 may be electrically connected to and in contact with the drain electrode DE of the transistor TR through a contact hole passing through the first planarization layer 140 in the third direction DR3.

Although not illustrated, the second connection electrode 155 may be electrically connected to a common power terminal (high-potential voltage terminal) and may receive and transmit common power.

A second planarization layer 160 may be disposed on the first connection electrode 151 and the second connection electrode 155. The second planarization layer 160 may be disposed to cover the first connection electrode 151 and the second connection electrode 155. The second planarization layer 160 may be made of an organic material. For example, the second planarization layer 160 may be made of an acrylic-based organic material but is not limited thereto. The second planarization layer 160 may be made of the same material as the first planarization layer 140 but is not limited thereto.

A third connection electrode 171 and a fourth connection electrode 175 may be disposed on the second planarization layer 160. The third connection electrode 171 and a fourth connection electrode 175 may be disposed to cover the second planarization layer 160. The third connection electrode 171 and the fourth connection electrode 175 may include the same material as the first connection electrode 151 and the second connection electrode 155 but are not limited thereto.

The third connection electrode 171 may overlap the first connection electrode 151 in the third direction DR3 (or thickness direction). The third connection electrode 171 may be electrically connected to and in contact with the first connection electrode 151 through a contact hole passing through the second planarization layer 160 in the third direction DR3.

The fourth connection electrode 175 may overlap the second connection electrode 155 in the third direction DR3 (or thickness direction). The fourth connection electrode 175 may be electrically connected to and in contact with the second connection electrode 155 through a contact hole passing through the second planarization layer 160 in the third direction DR3.

An adhesive layer 180 may be disposed on the third connection electrode 171 and the fourth connection electrode 175. The adhesive layer 180 may be disposed over the entire area of the second planarization layer 160 while covering the third connection electrode 171 and the fourth connection electrode 175.

The adhesive layer 180 may fix the light-emitting element LD disposed on the adhesive layer 180. The adhesive layer 180 may be formed of an organic insulating layer. The adhesive layer 180 may be made of a photocurable adhesive material which may be cured by light. For example, the adhesive layer 180 may be made of an acrylic-based material containing a photosensitive agent, but is not limited thereto.

The light-emitting element LD may be disposed on the adhesive layer 180. The light-emitting element LD may be an LED or micro LED, but is not limited thereto. The light-emitting element LD may have a vertical structure, but is not limited thereto.

The light-emitting element LD may include a first electrode 210, the light-emitting layer 220, a second electrode 230, and a passivation film 240. The light-emitting layer 220 may include a first semiconductor layer 221, an active layer 222, and a second semiconductor layer 223. When the light-emitting element LD has a vertical structure, the first electrode 210, the first semiconductor layer 221, the active layer 222, the second semiconductor layer 223, and the second electrode 230 may overlap in the thickness direction (third direction DR3). For example, the first electrode 210 may be disposed on the adhesive layer 180. The first semiconductor layer 221, the active layer 222 and the second semiconductor layer 223 may be disposed on the first electrode 210.

The first electrode 210, the light-emitting layer 220, and the second electrode 230 may be sequentially disposed in the thickness direction (third direction DR3). The first electrode 210, the light-emitting layer 220, and the second electrode 230 may overlap in the thickness direction (third direction DR3). The light-emitting layer 220 may be disposed between the first electrode 210 and the second electrode 230. The active layer 222 of the light-emitting layer 220 may be disposed between the first semiconductor layer 221 and the second semiconductor layer 223 of the light-emitting layer 220.

The first electrode 210 may be disposed between the adhesive layer 180 and the light-emitting layer 220. The first electrode 210 may be one of an anode electrodes and a cathode electrode. For example, the first electrode 210 may be a cathode electrode, but is not limited thereto.

When the first electrode 210 is the cathode electrode, the first electrode 210 may be electrically connected to the common voltage terminal (or high-potential voltage terminal). When the first electrode 210 is the cathode electrode, the common voltage terminal (or the high-potential voltage terminal) and the first semiconductor layer 221 may be electrically connected through the first electrode 210.

The first electrode 210 may include a conductive material. The conductive material may be made of at least one selected from, for example, transparent conductive materials, such as ITO, IZO, etc., or opaque conductive materials, such as nickel (Ni), gold (Au), platinum (Pt), titanium (Ti), aluminum (Al), chromium (Cr), copper (Cu), silver (Ag), or an alloy thereof, but is not limited thereto.

The light-emitting layer 220 may be disposed on the first electrode 210. The first semiconductor layer 221, the active layer 222, and the second semiconductor layer 223 of the light-emitting layer 220 may be sequentially disposed on the first electrode 210 in the thickness direction. The active layer 222 may be disposed between the first semiconductor layer 221 and the second semiconductor layer 223.

For example, the light-emitting layer 220 may include one or more of a hole injection layer (HIL), a hole transmitting layer (HTL), an electron transmitting layer (ETL) and an electron injection layer (EIL), but the present disclosure is not limited thereto.

The first semiconductor layer 221 may be disposed on the first electrode 210. The first semiconductor layer 221 may be disposed between the first electrode 210 and the active layer 222. The first semiconductor layer 221 may include a first-type dopant. For example, the first semiconductor layer 221 may include an n-type dopant but is not limited thereto.

When the first semiconductor layer 221 includes the n-type dopant, the first semiconductor layer 221 may supply electrons to the active layer 222 and have a material, such as gallium nitride (GaN), indium aluminum phosphide (InAlP), gallium arsenide (GaAs), etc., coated with impurities, such as silicon (Si), germanium (Ge), selenium (Se), tellurium (Te), etc.

The active layer 222 may be disposed on the first semiconductor layer 221. The active layer 222 may receive electrons and holes from the first semiconductor layer 221 and the second semiconductor layer 223 and emit light. The active layer 222 may be formed in a single-layer or multi-quantum well (MQW) structure and may be made of, for example, indium gallium nitride (InGaN), gallium nitride (GaN), etc., but is not limited thereto.

The second semiconductor layer 223 may be disposed on the active layer 222. The second semiconductor layer 223 may be disposed between the active layer 222 and the second electrode 230. The second semiconductor layer 223 may include a second-type dopant different from the first-type dopant. For example, the second semiconductor layer 223 may include a p-type dopant but is not limited thereto.

When the second semiconductor layer 223 includes the p-type dopant, the second semiconductor layer 223 may supply holes to the active layer 222 and have a material, such as gallium nitride (GaN), indium aluminum phosphide (InAlP), gallium arsenide (GaAs), etc., coated with impurities, such as magnesium (Mg), zinc (Zn), beryllium (Be), etc.

Although the first semiconductor layer 221 has been described as including the n-type dopant and the second semiconductor layer 223 including the p-type dopant, the inventive concepts are not limited thereto, and the first semiconductor layer 221 may include the p-type dopant and the second semiconductor layer 223 may include the n-type dopant. For example, the active layer 222 may receive holes and electrons from the first semiconductor layer 221 and the second semiconductor layer 223 and emit light.

The light-emitting layer 220 may have a mesa structure. A side surface of the light-emitting layer 220 may be formed as an inclined surface inclined with respect to the thickness direction (third direction DR3). A planar size of the light-emitting layer 220 may decrease from the first semiconductor layer 221 toward the second semiconductor layer 223. A width of the light-emitting layer 220 may decrease from the first semiconductor layer 221 toward the second semiconductor layer 223 but is not limited thereto.

The second electrode 230 may be disposed on the light-emitting layer 220. The second electrode 230 may be disposed on the second semiconductor layer 223 of the light-emitting layer 220. For example, the second electrode 230 may be disposed on the entire surface of the second semiconductor layer 223. The second electrode 230 may be one of an anode electrode or a cathode electrode. For example, when the first electrode 210 is the cathode electrode, the second electrode 230 may be the anode electrode, but is not limited thereto. For example, when the first electrode 210 is the anode electrode, the second electrode 230 may be the cathode electrode.

Although the first electrode 210 is being described with reference to the cathode electrode and the second electrode 230 with reference to the anode electrode, the inventive concepts are not limited thereto. For example, the first electrode 210 may be the anode electrode and the second electrode 230 may be the cathode electrode.

When the second electrode 230 is the anode electrode, the second electrode 230 may be electrically connected to the transistor TR. When the second electrode 230 is the anode electrode, the transistor TR and the second semiconductor layer 223 may be electrically connected through the second electrode 230.

The second electrode 230 may include a conductive material. The conductive material may be made of at least one selected from, for example, transparent conductive materials, such as ITO, IZO, etc., or opaque conductive materials, such as nickel (Ni), gold (Au), platinum (Pt), titanium (Ti), aluminum (Al), chromium (Cr), copper (Cu), silver (Ag), or an alloy thereof, but is not limited thereto.

The passivation film 240 may be disposed on the side surface of the light-emitting layer 220. The passivation film 240 may be disposed along the perimeter of the light-emitting layer 220 and disposed to surround the light-emitting layer 220.

The passivation film 240 may come into direct contact with the side surface of the light-emitting layer 220. The passivation film 240 may be disposed on side surfaces of the first semiconductor layer 221, the active layer 222, and the second semiconductor layer 223. The passivation film 240 may come into direct contact with the side surfaces of the first semiconductor layer 221, the active layer 222, and the second semiconductor layer 223.

The passivation film 240 may be made of an inorganic insulation material, such as silicon oxide, silicon nitride, silicon oxynitride, aluminum oxide, etc., but is not limited thereto.

The passivation film 240 may protect the light-emitting layer 220, prevent or at least reduce leakage current flowing to the side of the light-emitting layer 220, and suppress, prevent or at least reduce short circuits between the light-emitting layer 220 and connection electrodes 195 and 250.

A common connection electrode 195 may be disposed on the adhesive layer 180. The common connection electrode 195 may be in contact with the light-emitting element LD. The common connection electrode 195 may be made of the same material as a pixel connection electrode 250 but is not limited thereto.

The adhesive layer 180 may define a first through-hole TH1 that passes through in the thickness direction (third direction DR3) to expose the fourth connection electrode 175. The common connection electrode 195 may be disposed on the fourth connection electrode 175 through the first through-hole TH1.

The common connection electrode 195 may be electrically connected to and in contact with the first electrode 210. For example, the common connection electrode 195 may be in direct contact with side surfaces of the first electrode 210. Through the first through-hole TH1, the common connection electrode 195 may be electrically connected to and in contact with the fourth connection electrode 175 exposed by the first through-hole TH1. For example, the first electrode 210 and the fourth connection electrode 175 may be electrically connected by the common connection electrode 195.

A portion of the first electrode 210 may be disposed between outer surfaces of the common connection electrode 195 and the passivation film 240.

The common connection electrode 195 may come into direct contact with side surfaces of the first electrode 210. The common connection electrode 195 may be disposed to surround the first electrode 210 along the perimeter of the first electrode 210. Accordingly, since a contact area between the common connection electrode 195 and the first electrode 210 can be increased, the light-emitting element LD and the common connection electrode 195 can be more smoothly electrically connected. Furthermore, the electrical characteristics of the display apparatus 10 can be improved, enabling low-voltage driving or improving light efficiency or luminance by applying a higher voltage.

The first electrode 210 may protrude outward from the side surface of the light-emitting layer 220. The first electrode 210 may protrude further outward than side surfaces of the passivation film 240. The planar size (area) of the first electrode 210 may be larger than that of the light-emitting layer 220.

The first electrode 210 may overlap the entire area of the light-emitting layer 220 in the thickness direction (third direction DR3). The first electrode 210 may overlap the entire area of the passivation film 240 in the thickness direction (third direction DR3).

The first electrode 210 may extend along an outer surface of the passivation film 240 in the thickness direction (third direction DR3). The first electrode 210 may extend along the outer surface of the passivation film 240 in the thickness direction (third direction DR3) near the edge of the passivation film 240. A portion of the passivation film 240 may be disposed between the light-emitting layer 220 and the first electrode 210. A portion of the first electrode 210 may be disposed between the passivation film 240 and the common connection electrode 195.

The first electrode 210 may extend in the thickness direction (third direction DR3) in an area that protrudes further outward than the side surface of the passivation film 240 and may be disposed on a portion of the outer surface of the passivation film 240. The first electrode 210 may come into direct contact with the portion of the outer surface and lower surface of the passivation film 240.

An inner surface of the passivation film 240 may be disposed on the light-emitting layer 220 such that it directly contact the light-emitting layer 220. The portion of the outer surface of the passivation film 240 may be covered by the first electrode 210. For example, the lower portion of the outer surface of the passivation film 240 may be overlapped and covered by the first electrode 210, allowing the first electrode 210 to directly contact the outer surface of the passivation film 240. Accordingly, at least a portion of the passivation film 240 may be disposed between the first electrode 210 and the light-emitting layer 220.

As the first electrode 210 extends along the outer surface of the passivation film 240 in the thickness direction (third direction DR3), the contact area between the first electrode 210 and the common connection electrode 195 may increase. As a result, the electrical characteristics of the display apparatus 10 may be further enhanced, enabling smoother low-voltage driving. Alternatively, a higher voltage may be applied more stably, thereby improving light efficiency and luminance.

A first insulating layer 190 and a second insulating layer 200 may be sequentially disposed on the common connection electrode 195. The first insulating layer 190 may be disposed between the adhesive layer 180 and the second insulating layer 200. For example, the first insulating layer 190 may be disposed between the adhesive layer 180, the common connection electrode 195 and the second insulating layer 200.

The first insulating layer 190 and the second insulating layer 200 may be disposed on the adhesive layer 180 while covering the common connection electrode 195. The second insulating layer 200 may cover at least a portion of the light-emitting element LD. The first insulating layer 190 and the second insulating layer 200 may be formed with a thickness sufficient to completely cover the light-emitting element LD.

The first insulating layer 190 and the second insulating layer 200 may provide a flat surface on the transistor TR and the light-emitting element LD and fix the position of the light-emitting element LD.

The pixel connection electrode 250 may be disposed on the second insulating layer 200. The pixel connection electrode 250 may contact the upper surface and side surfaces of the second electrode 230. The adhesive layer 180, the first insulating layer 190, and the second insulating layer 200 may define a second through-hole TH2 extending in the thickness direction (third direction DR3) to expose the third connection electrode 171. The second insulating layer 200 may further define an opening OP that passes through in the thickness direction (third direction DR3) to expose the light-emitting element LD. The opening OP may expose the second electrode 230.

Through the opening OP, the pixel connection electrode 250 may be electrically connected to and in contact with the second electrode 230 exposed by the opening OP.

Through the second through-hole TH2, the pixel connection electrode 250 may be electrically connected to, and in direct contact with, the third connection electrode 171 exposed by the second through-hole TH2. For example, the second electrode 230 and the third connection electrode 171 may be electrically connected via the pixel connection electrode 250.

The pixel connection electrode 250 may be formed of a transparent conductive material when the display apparatus 10 is configured as a top-emission type, or of a light-reflecting conductive material when the display apparatus 10 is configured as a bottom-emission type. The transparent conductive material may include ITO, IZO, or similar materials, but is not limited thereto. The light-reflecting conductive material may include Al, Ag, Au, Pt, Cu, or similar materials, but is not limited thereto. The pixel connection electrode 250 formed of the light-reflecting conductive material may be implemented as a single layer containing the light-reflecting conductive material or a multilayer structure in which single layers are stacked.

The opening OP may be larger than the second electrode 230. A sidewall of the opening OP may be formed of the second insulating layer 200, and the sidewall of the opening OP may be disposed to be spaced apart from the second electrode 230 and may surround the second electrode 230.

The opening OP may overlap the entire area of the second electrode 230 in the thickness direction (third direction DR3). The entire area of the second electrode 230 may be disposed within the opening OP.

The opening OP may expose all of an upper surface and side surfaces of the second electrode 230 and expose a portion of an upper side of the passivation film 240, but is not limited thereto.

At least a portion of the pixel connection electrode 250 may be disposed within the opening OP. When the opening OP exposes the entire upper surface and side surfaces of the second electrode 230, the pixel connection electrode 250 may contact all of the exposed upper surface and side surfaces of the second electrode 230. The pixel connection electrode 250 may come into direct contact with all of the upper surface and side surfaces of the second electrode 230 exposed by the opening OP. Here, the upper surface of the second electrode 230 may refer to the surface opposite the lower surface of the second electrode 230 that faces the light-emitting layer 220.

When the opening OP exposes a portion of the passivation film 240, the pixel connection electrode 250 may come into direct contact with the passivation film 240 exposed by the opening OP. The pixel connection electrode 250 may come into direct contact with an upper surface and outer surface of the passivation film 240 exposed by the opening OP.

As the opening OP exposes the entire upper and side surfaces of the second electrode 230, the contact area between the second electrode 230 and the pixel connection electrode 250 may increase. Accordingly, the electrical characteristics of the display apparatus 10 may be further enhanced, enabling smoother low-voltage driving. Alternatively, a higher voltage may be applied more stably, thereby improving light efficiency and luminance.

Hereinafter, a method of manufacturing the display apparatus 1 according to an embodiment will be described. While describing the method of manufacturing the display apparatus 1 according to one embodiment, the descriptions of parts already described in FIGS. 1, 2, and 3, will be briefly given or omitted.

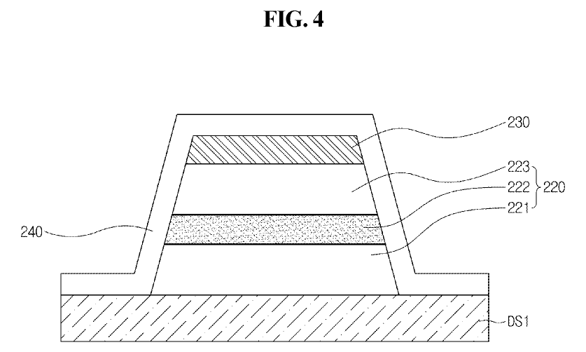

FIGS. 4, 5, 6, 7, 8, 9, 10, 11, and 12 are schematic views illustrating each operation of a process of manufacturing the display apparatus according to an embodiment.

Referring to FIG. 4, the first semiconductor layer 221, the active layer 222, and the second semiconductor layer 223 may be epitaxially grown on the entire surface of a first dummy substrate DS1. During this process, the first semiconductor layer 221 and the second semiconductor layer 223 may each be doped with one of a first-type dopant and a second-type dopant. The second electrode 230 may be formed over the entire surface of the second semiconductor layer 223. A width of the light-emitting layer 220 may decrease from the first semiconductor layer 221 toward the second semiconductor layer 223, but this configuration is not limited thereto.

The first semiconductor layer 221, the active layer 222, the second semiconductor layer 223, and the second electrode 230, which are formed over the entire surface of the first dummy substrate DS1, may be patterned to form a plurality of independent island structures. Although FIG. 4 illustrates only a single island‑shaped structure for convenience of explanation, various embodiments of the present disclosure are not limited thereto, and multiple island-shaped portions may be formed.

After the first semiconductor layer 221, the active layer 222, the second semiconductor layer 223, and the second electrode 230 may be patterned, the passivation film 240 may be formed. The passivation film 240 may be formed over the entire surface of the first dummy substrate DS1 while covering the first semiconductor layer 221, the active layer 222, the second semiconductor layer 223, and the second electrode 230 that are patterned. For example, the passivation film 240 may be formed to cover the side surfaces of the light-emitting layer 220 and upper and side surfaces of the second electrode 230.

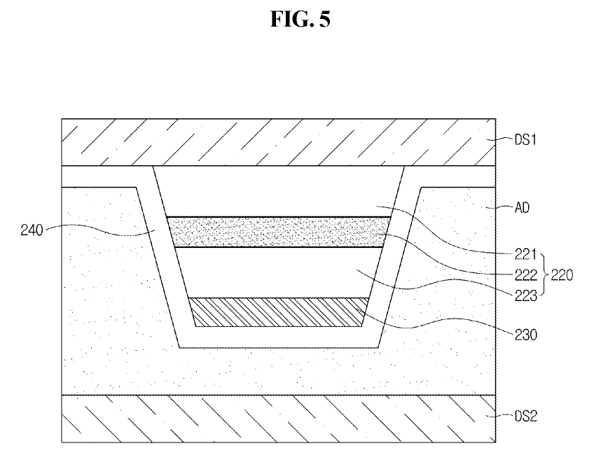

Next, referring further to FIG. 5, the passivation film 240 and the patterned structure of the first semiconductor layer 221, the active layer 222, the second semiconductor layer 223, and the second electrode 230 may be attached to a second dummy substrate DS2 through an adhesive AD. The adhesive AD may be disposed across the entire region between the first dummy substrate DS1 and the second dummy substrate DS2.

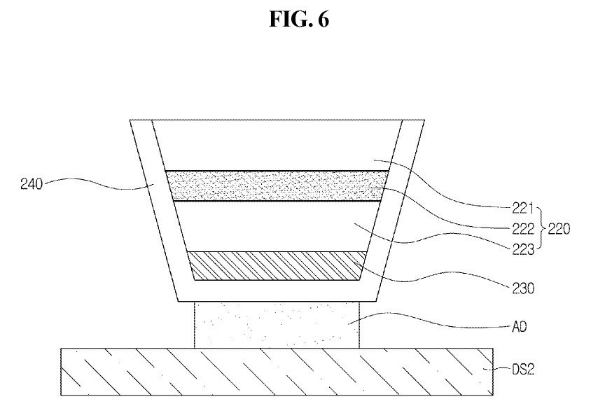

Next, referring to FIG. 6, the first dummy substrate DS1 and a portion of the passivation film 240 in direct contact with the first dummy substrate DS1 are removed, and a portion of the adhesive AD is removed. The remaining adhesive AD may expose the side surfaces of the passivation film 240 and may be disposed in an island shape between the passivation film 240 and the second dummy substrate DS2.

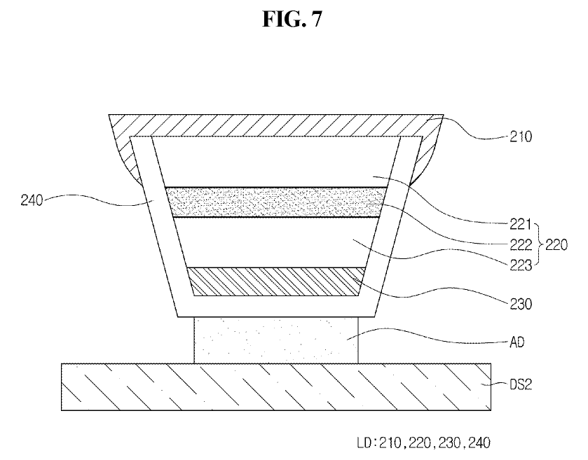

Next, referring to FIG. 7, the first electrode 210 may be formed on the exposed first semiconductor layer 221. By forming the first electrode 210 on the exposed first semiconductor layer 221, the light-emitting element LD may be formed. The first electrode 210 may be formed not only on the exposed first semiconductor layer 221, but also so as to extend along the side surfaces of the passivation film 240. For example, the side surfaces of the first electrode 210 may protrude outward beyond the outer surface of the passivation film 240. A portion of the first electrode 210 may be disposed on the outer surface of the passivation film 240.

By first patterning the first semiconductor layer 221, the active layer 222, the second semiconductor layer 223, and the second electrode 230 and subsequently forming the first electrode 210 on the first semiconductor layer 221, the first electrode 210 may be formed to protrude outward beyond the side surfaces of the first semiconductor layer 221. Furthermore, the first electrode 210 may be formed to extend along the side surfaces of the passivation film 240. A portion of the first electrode 210 may extend onto the outer surface of the passivation film 240, although various embodiments are not limited thereto.

Accordingly, since the contact area between the common connection electrode 195 and the first electrode 210 can be increased, the light-emitting element LD and the common connection electrode 195 can be more smoothly electrically connected.

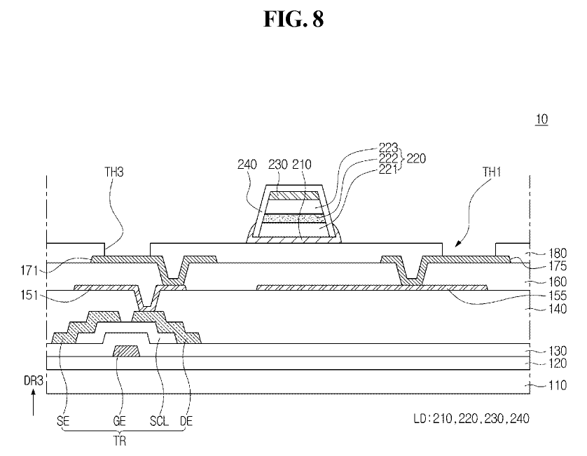

Next, referring to FIG. 8, the light-emitting element LD is transferred onto the substrate 110 on which the buffer layer 120, the transistor TR, the gate insulating layer 130, the first planarization layer 140, the second planarization layer 160, the adhesive layer 180, and the connection electrodes 151, 155, 171, and 175 may be disposed. The light-emitting element LD may be transferred onto the adhesive layer 180.

The adhesive layer 180 may define the first through-hole TH1 that exposes the fourth connection electrode 175 and a third through-hole TH3 that exposes the third connection electrode 171. The third through-hole TH3 may correspond to a portion of the second through-hole TH2 illustrated in FIG. 2. The light-emitting element LD may be transferred onto the portion of the adhesive layer 180 excluding the regions of the first through‑hole TH1 and the third through‑hole TH3.

After the light-emitting element LD is transferred, a lighting test may be performed to determine whether the light-emitting element LD is operating normally.

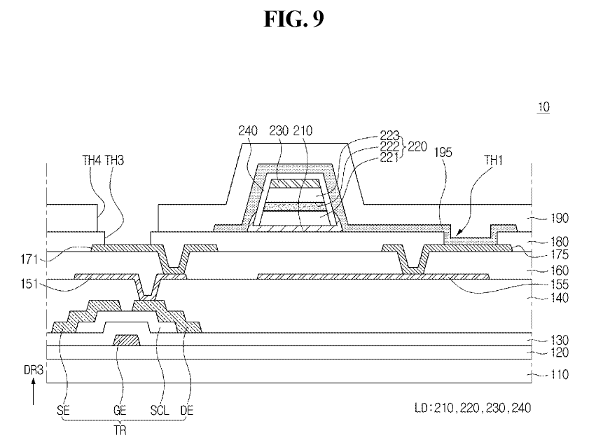

Next, referring to FIG. 9, the common connection electrode 195 and the first insulating layer 190 are formed.

The common connection electrode 195 may extend to the first through-hole TH1 while covering the entire area of the light-emitting element LD. Accordingly, the common connection electrode 195 may be electrically connected to and in contact with the first electrode 210 and the fourth connection electrode 175.

The first insulating layer 190 may be formed on the adhesive layer 180 while covering the common connection electrode 195. The first insulating layer 190 may be patterned in an area in which the third through-hole TH3 is located so as to expose the third through-hole TH3, thereby defining the fourth through-hole TH4. A width of the fourth through-hole TH4 may be greater than that of the third through-hole TH3, although various embodiments are not limited thereto. The fourth through-hole TH4 passing through the first insulating layer 190 may overlap the third through-hole TH3 passing through the adhesive layer 180.

As illustrated in FIGS. 8 and 9, by transferring the light-emitting element LD and forming the conductive layer (such as the common connection electrode 195) separately, the stability of individual process may be improved. In addition, the stability of the process in which the light‑emitting element LD comes into contact with the conductive layer (such as the common connection electrode 195) may also be enhanced. Accordingly, overall process efficiency may be improved, manufacturing costs may be reduced, and production energy consumption may likewise be decreased.

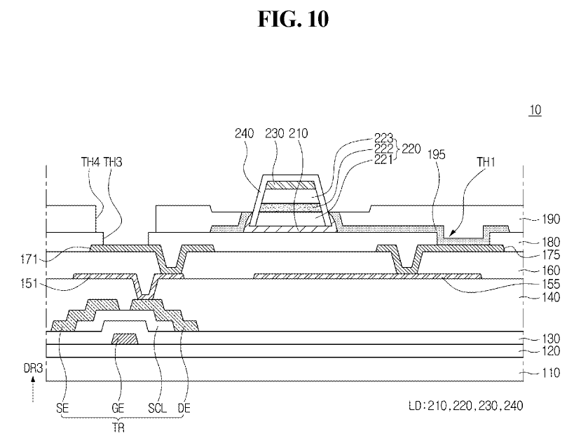

Next, referring to FIG. 10, a portion of the first insulating layer 190 and a portion of the common connection electrode 195 may be etched. The etching process may be performed using dry etching, but is not limited thereto.

Through the etching process, the portion of the first insulating layer 190 and the portion of the common connection electrode 195 that are disposed on the light-emitting element LD may be removed. A portion of the common connection electrode 195 that does not come into contact with the first electrode 210 may be removed, and the portion of the first insulating layer 190 disposed on the corresponding region of the common connection electrode 195 may also be removed. The upper surface of the common connection electrode 195 exposed by etching may be at substantially the same height as the upper surface of the surrounding first insulating layer 190, although various embodiments are not limited thereto.

As the portion of the first insulating layer 190 and the portion of the common connection electrode 195 are removed, a portion of the passivation film 240 disposed on the light-emitting element LD may be exposed. For example, a lower portion of the passivation film 240 may be covered by the first insulating layer 190 and the common connection electrode 195, and the upper portion of the passivation film 240 may be exposed.

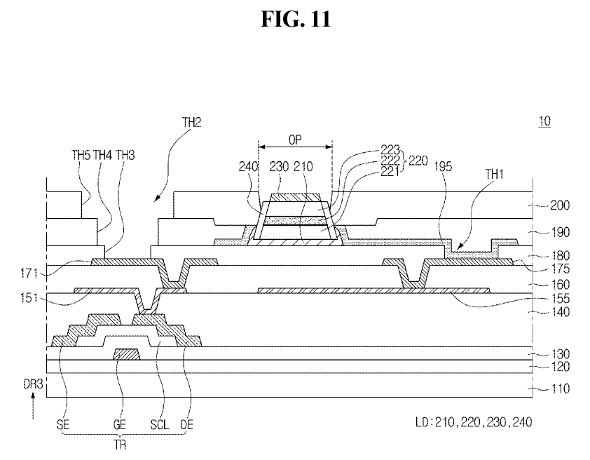

Next, referring to FIG. 11, the second insulating layer 200 is formed on the first insulating layer 190.

The second insulating layer 200 may be patterned to define a fifth through-hole TH5 that exposes the third through-hole TH3 and the fourth through-hole TH4. Accordingly, the second through-hole TH2 may be formed. For example, the width of the fifth through-hole TH5 may be greater than the widths of the third through-hole TH3 and the fourth through-hole TH4, although various embodiments are not limited thereto.

The second insulating layer 200 may be patterned to define the opening OP that exposes the second electrode 230 and the passivation film 240. During the patterning process of the second insulating layer 200, the passivation film 240 covering the second electrode 230 may also be removed. However, various embodiments of the present disclosure are not limited thereto, and the passivation film 240 covering the second electrode 230 may be removed through a separate etching process.

The opening OP may be formed to have a size greater than that of the second electrode 230, and the sidewalls of the opening OP may configured to surround the second electrode 230. The opening OP may overlap the entire area of the second electrode 230 in the thickness direction (third direction DR3). Accordingly, the entire area of the second electrode 230 may be disposed within the opening OP.

Accordingly, the side surfaces and upper surface of the second electrode 230 may be exposed, and the second electrode 230 may come into contact with the pixel connection electrode 250 across the side surfaces and upper surface thereof. For example, the area in which the second electrode 230 may contact the pixel connection electrode 250 may be increased. For example, the pixel connection electrode 250 may cover the side surfaces and the upper surface of the second electrode 230.

In addition, a tolerance required for the alignment of the second electrode 230 and the pixel connection electrode 250 can be increased, thereby performing the process more efficiently and reducing process time and cost.

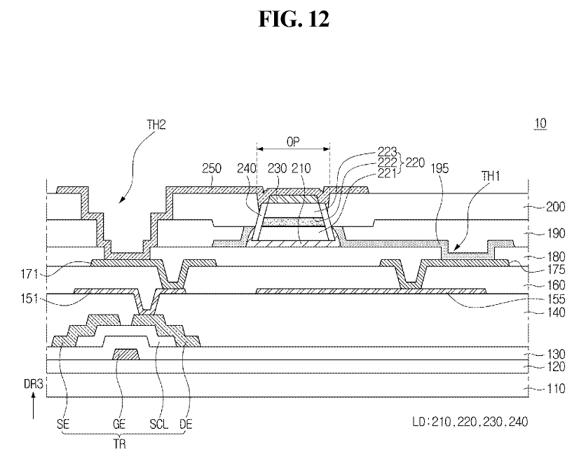

Next, referring to FIG. 12, the pixel connection electrode 250 is formed on the second insulating layer 200.

The pixel connection electrode 250 may be patterned and may have one end disposed within the second through-hole TH2 to come into contact with the third connection electrode 171 and the other end disposed within the opening OP to come into contact with the second electrode 230. The second electrode 230 and the third connection electrode 171 may be electrically connected by the pixel connection electrode 250.

Although not illustrated, after the pixel connection electrode 250 is patterned, a black matrix may be further disposed over the second through-hole TH2, the second insulating layer 200, and the pixel connection electrode 250. The black matrix may be disposed across the entire area of the display area DA (see FIG. 1), excluding the light-emitting area of each pixel PX (see FIG. 1).

An upper protective layer, a cover glass, etc., may be further disposed on the black matrix to planarize an upper portion and protect underlying components.

A plurality of light-emitting elements LD may be disposed for each of the plurality of sub-pixels, but various embodiments are not limited thereto. A plurality of light-emitting elements LD may be disposed for each of the sub-pixels SP1, SP2, and SP3 (see FIG. 1). For example, two light-emitting elements LD may be transferred onto each of the sub-pixels SP1, SP2, and SP3 (see FIG. 1), but various embodiments are not limited thereto. More or fewer light-emitting elements LD may be transferred onto each of the plurality of` sub-pixels.

Accordingly, when one of the two light-emitting elements LD disposed in each of the sub-pixels SP1, SP2, and SP3 (see FIG. 1) is defective, light may be emitted from the corresponding sub-pixel SP1, SP2, or SP3 (see FIG. 1) through the other light-emitting element LD. Alternatively, the two light-emitting elements LD disposed in each of the sub-pixels SP1, SP2, and SP3 (see FIG. 1) may operate as redundant LEDs that emit light.

Hereinafter, other embodiments of the present disclosure will be described. For contents that are substantially the same as those described with reference to FIGS. 1 to 12 among components included in other embodiments, the same reference numerals may be given, and the overlapping contents may be omitted or briefly described.

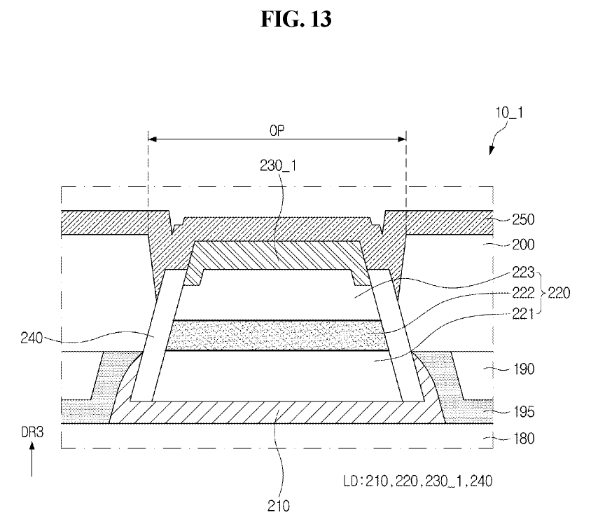

FIG. 13 is a schematic cross-sectional view of a display apparatus according to another embodiment. FIG. 13 is an enlarged view of an area surrounding the light-emitting element LD.

Referring to FIG. 13, a display apparatus 10_1 according to another embodiment may include the light-emitting element LD. A second electrode 230_1 of the light-emitting element LD may extend to protrude toward the second semiconductor layer 223 near side surfaces thereof. The second electrode 230_1 may be thicker in regions adjacent to the side surfaces. Accordingly, the second semiconductor layer 223 may be thinner near the side surface regions.

A portion of the second electrode 230_1 may be disposed between the second semiconductor layer 223 and the passivation film 240. The second electrode 230_1 protruding toward the second semiconductor layer 223 may be disposed between the second semiconductor layer 223 and the passivation film 240. For example, the second electrode 230_1 protruding toward the second semiconductor layer 223 may be disposed between the side surface of the second semiconductor layer 223 and the passivation film 240.

As illustrated in FIG. 4, the first semiconductor layer 221, the active layer 222, and the second semiconductor layer 223 may be epitaxially grown, after which the second semiconductor layer 223 may be patterned. By patterning the second semiconductor layer 223, the layer may be formed to have different thicknesses in different regions, with certain regions protruding further than others. For example, the second semiconductor layer 223 may be thinner near its side surfaces.

By forming the second electrode 230_1 on the patterned second semiconductor layer 223, the second electrode 230_1 may be formed to protrude and extend toward the second semiconductor layer 223 near the side surfaces thereof.

The side surfaces of the second electrode 230_1 may be positioned closer to the light-emitting layer 220. Accordingly, non-luminous coupling that may occur at the side surfaces of the second electrode 230_1 may be reduced, and current leakage along the side surfaces may be suppressed, prevented or at least reduced. As a result, the luminous efficiency of the light-emitting element LD may be improved.

Even in this case, the contact area between the common connection electrode 195 and the first electrode 210 and the contact area between the pixel connection electrode 250 and the second electrode 230_1 can be increased, thereby improving the electrical characteristics of the display apparatus 10_1, enabling low-voltage driving, or a higher voltage may be applied, thereby improving light efficiency or luminance.

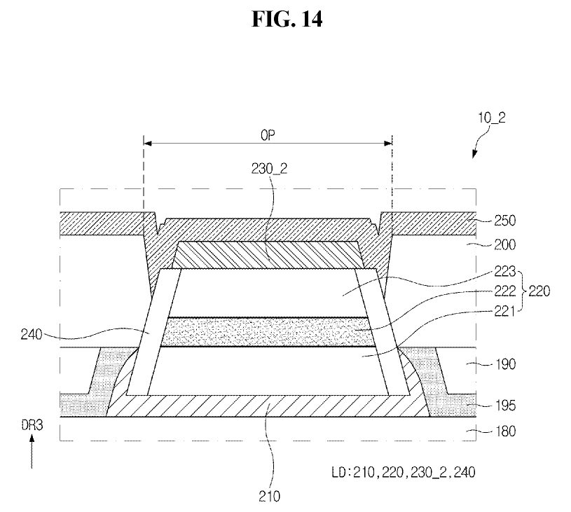

FIG. 14 is a schematic cross-sectional view of a display apparatus according to still another embodiment. FIG. 14 is an enlarged view of an area surrounding the light-emitting element LD.

Referring to FIG. 14, a display apparatus 10_2 according to still another embodiment may include the light-emitting element LD. A second electrode 230_2 may be larger than the second semiconductor layer 223.

For example, the second electrode 230_2 may be disposed on the second semiconductor layer 223 and on a portion of the passivation film 240. The second electrode 230_2 may cover an upper surface of the second semiconductor layer 223 and a portion of an upper side of the passivation film 240.

The second electrode 230_2 may protrude outward beyond the side surfaces of the second semiconductor layer 223. The second electrode 230_2 may be disposed on the upper surface of the passivation film 240 and may come into direct contact with the upper surface of the passivation film 240.

The outer surface of the passivation film 240 may be disposed further outward than side surfaces of the second electrode 230_2. The side surfaces of the second electrode 230_2 may be disposed between the outer and inner surfaces of the passivation film 240.

The second electrode 230_2 may overlap the passivation film 240 in the thickness direction (third direction DR3). For example, the second electrode 230_2 may overlap the second semiconductor layer 223 and a portion of the passivation film 240 in the thickness direction (third direction DR3).

As illustrated in FIG. 4, the first semiconductor layer 221, the active layer 222, and the second semiconductor layer 223 may be epitaxially grown and then immediately patterned. The passivation film 240 may be formed on the patterned first semiconductor layer 221, the active layer 222, and the second semiconductor layer 223, and a portion of the passivation film 240 may be removed to expose the second semiconductor layer 223.

Thereafter, the second electrode 230_2 may be formed on the second semiconductor layer 223 exposed by the passivation film 240. Accordingly, the second electrode 230_2 may be formed across the second semiconductor layer 223 and the passivation film 240.

Even in this case, the contact area between the common connection electrode 195 and the first electrode 210, as well as the contact area between the pixel connection electrode 250 and the second electrode 230_2, can be increased. As a result, the electrical characteristics of the display apparatus 10_2 may be improved, enabling low-voltage driving. Alternatively, a higher voltage may be applied more stably, thereby enhancing light efficiency or luminance.

According to embodiments of the present disclosure, the display apparatus and a method of manufacturing the same, may provide a smooth electrical connection with the LED element.

According to embodiments of the present disclosure, the display apparatus and a method of manufacturing the same, may improve stability during a contact process with the LED element.

According to embodiments of the present disclosure, the display apparatus and a method of manufacturing the same, may improve light extraction efficiency.

According to embodiments of the present disclosure, the display apparatus and a method of manufacturing the same, may prevent or at least reduce a short circuit between the connection electrode and the active layer.

According to embodiments of the present disclosure, process efficiency of the display apparatus may be improved and process costs may be reduced by separating the transfer process from the electrode connection process.

According to embodiments of the present disclosure, it is possible to improve process efficiency and reduce process costs, thereby reducing the production energy of the display apparatus.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a substrate;
a light-emitting element disposed on the substrate; and
a common connection electrode associated with the substrate and configured to electrically couple to the light-emitting element,
wherein the light-emitting element includes:
a first electrode disposed on the substrate;
a light-emitting layer disposed on the first electrode;
a second electrode disposed on the light-emitting layer; and
a passivation film covering at least side portions of the light-emitting layer, and
wherein the first electrode extends beyond the passivation film such that a portion of the first electrode is located outward of the passivation film.

2. The display apparatus of claim 1, wherein the common connection electrode contacts side surfaces of the first electrode.

3. The display apparatus of claim 2, wherein the common connection electrode is configured to be applied with a high-potential voltage.

4. The display apparatus of claim 1, wherein a planar size of the first electrode is greater than a planar size of the light-emitting layer.

5. The display apparatus of claim 4, wherein an entire area of the light-emitting layer overlaps the first electrode in a thickness direction.

6. The display apparatus of claim 1, wherein side surfaces of the first electrode protrude further outward than an outer surface of the passivation film.

7. The display apparatus of claim 6, wherein the first electrode extends along the outer surface of the passivation film near edges of the passivation film.

8. The display apparatus of claim 1, wherein a portion of the passivation film is disposed between the light-emitting layer and the first electrode.

9. The display apparatus of claim 8, wherein the passivation film surrounds the light-emitting layer along edges of the light-emitting layer.

10. The display apparatus of claim 1, wherein the first electrode contacts an outer surface of the passivation film.

11. The display apparatus of claim 1, further comprising an adhesive layer disposed on the substrate, a first insulating layer disposed on the adhesive layer, and a second insulating layer disposed on the first insulating layer,
wherein the first insulating layer and the second insulating layer cover at least a portion of the light-emitting element, and
wherein the second insulating layer defines an opening exposing side surfaces and an upper surface of the second electrode.

12. The display apparatus of claim 11, further comprising a pixel connection electrode disposed on the second insulating layer,
wherein the pixel connection electrode contacts the upper surface and side surfaces of the second electrode exposed by the opening.

13. The display apparatus of claim 12, further comprising a transistor disposed on the substrate,
wherein the pixel connection electrode is electrically connected to the transistor.

14. The display apparatus of claim 13, further comprising:
a first planarization layer disposed on the transistor; and
a first connection electrode and a second connection electrode disposed on the first planarization layer,
wherein the first connection electrode is electrically connected to the transistor.

15. The display apparatus of claim 14, further comprising:
a second planarization layer disposed on the first connection electrode and the second connection electrode; and
a third connection electrode and a fourth connection electrode disposed on the second planarization layer,
wherein the third connection electrode is electrically connected to the first connection electrode, and the fourth connection electrode is electrically connected to the second connection electrode.

16. The display apparatus of claim 15, wherein the adhesive layer, the first insulating layer, and the second insulating layer define a second through-hole exposing the third connection electrode, and
wherein the pixel connection electrode is electrically connected to the third connection electrode exposed by the second through-hole.

17. The display apparatus of claim 11, wherein the opening further exposes a portion of the passivation film.

18. The display apparatus of claim 17, further comprising a pixel connection electrode disposed on the second insulating layer,
wherein the pixel connection electrode contacts the passivation film exposed by the opening.

19. The display apparatus of claim 1, wherein the light-emitting layer comprises:
a first semiconductor layer disposed on the first electrode;
an active layer disposed on the first semiconductor layer; and
a second semiconductor layer disposed on the active layer, and
wherein a width of the light-emitting layer decreases from the first semiconductor layer toward the second semiconductor layer.

20. The display apparatus of claim 1, wherein side surfaces of the second electrode protrude further toward the light-emitting layer than other regions of the second electrode.

21. The display apparatus of claim 1, wherein the second electrode overlaps the passivation film in a thickness direction.

22. A display apparatus comprising:
a substrate;
an adhesive layer disposed on the substrate;
a light-emitting element disposed on the adhesive layer,
wherein the light-emitting element includes:
a first electrode disposed on the adhesive layer;
a light-emitting layer disposed on the first electrode;
a second electrode disposed on the light-emitting layer; and
a passivation film covering at least side regions of the light-emitting layer, and
wherein an upper surface and side surfaces of the second electrode are exposed.

23. The display apparatus of claim 22, further comprising:
a first insulating layer disposed on the adhesive layer and covering a portion of a lower portion of the light-emitting element;
a second insulating layer disposed on the first insulating layer; and
a common connection electrode disposed between the adhesive layer and the first insulating layer,
wherein the common connection electrode contacts side surfaces of the first electrode.

24. The display apparatus of claim 23, wherein side surfaces of the first electrode protrude further outward than an outer surface of the passivation film.

25. The display apparatus of claim 23, further comprising a pixel connection electrode disposed on the second insulating layer,
wherein the second insulating layer defines an opening exposing an upper surface and side surfaces of the second electrode, and
wherein the pixel connection electrode contacts the upper surface and side surfaces of the second electrode exposed by the opening.

26. The display apparatus of claim 22, wherein the first electrode extends beyond the passivation film such that a portion of the first electrode is located outward of the passivation film.
